(19) United States
(12) Patent Application Publication
(10) Pub. No.: US 2025/0047030 A1
(43) Pub. Date: Feb. 6, 2025

(54) CONNECTOR AND DISK DEVICE

(71) Applicants: Kabushiki Kaisha Toshiba, Tokyo (JP); Toshiba Electronic Devices & Storage Corporation, Tokyo (JP)

(72) Inventors: Hayato YAMAGUCHI, Yokohama Kanagawa (JP); Nobuhiro YAMAMOTO, Yokohama Kanagawa (JP); Taichi OKANO, Yokohama Kanagawa (JP); Masahide TAKAZAWA, Hachioji Tokyo (JP)

(21) Appl. No.: 18/598,185

(22) Filed: Mar. 7, 2024

(30) Foreign Application Priority Data
Jul. 31, 2023 (JP) 2023-124545

(51) Int. Cl. H01R 13/502; H01R 12/71; H01R 13/04

(52) U.S. Cl. CPC H01R 13/502; H01R 12/716; H01R 13/04

(57) ABSTRACT

According to one embodiment, a connector includes a housing, a plurality of first leads, and a metal component. The first leads are attached to the housing in alignment with each other in a first direction. Each of the first leads includes a first external terminal outside the housing. The metal component is provided with a first opening and is attached to the housing. The metal component includes two first junction terminals being aligned with the first external terminals of the first leads in the first direction outside the housing. The first opening is located in-between the two first junction terminals.

### CROSS-REFERENCE TO RELATED APPLICATIONS

This application is based upon and claims the benefit of priority from Japanese Patent Application No. 2023-124545, filed on Jul. 31, 2023; the entire contents of which are incorporated herein by reference.

### FIELD

Embodiments described herein relate generally to a connector and a disk device.

### BACKGROUND

A connector serves to electrically connect two components to each other. For example, in a disk device such as a hard disk drive, a connector is mounted on a substrate such as a flexible printed circuit board that electrically connects a controller to magnetic heads.

The connector may be generally soldered using flux. Flux may however contaminate a device having a connector mounted thereon, such as a disk device. For this reason, flux may be removed by cleaning. However, flux may run up a connector lead and enter a connector housing. In such a situation it is difficult to remove the flux.

### BRIEF DESCRIPTION OF THE DRAWINGS

FIG. 1 is an exemplary perspective view illustrating an HDD according to a first embodiment in an exploded manner;

FIG. 2 is an exemplary plan view schematically illustrating an FPC of the first embodiment;

FIG. 3 is an exemplary perspective view illustrating a relay connector of the first embodiment;

FIG. 4 is an exemplary plan view illustrating the FPC and the relay connector according to the first embodiment;

FIG. 5 is an exemplary cross-sectional view of the FPC and the relay connector of the first embodiment taken along line F5-F5 in FIG. 4;

FIG. 6 is an exemplary perspective view illustrating a reinforcing pin of the first embodiment;

FIG. 7 is an exemplary perspective view illustrating a reinforcing pin according to a second embodiment;

FIG. 8 is an exemplary perspective view illustrating a reinforcing pin according to a third embodiment;

FIG. 9 is an exemplary perspective view illustrating a reinforcing pin according to a fourth embodiment;

FIG. 10 is an exemplary plan view illustrating an FPC and a relay connector according to a fifth embodiment;

FIG. 11 is an exemplary cross-sectional view of the FPC and the relay connector of the fifth embodiment taken along line F11-F11 in FIG. 10;

FIG. 12 is an exemplary perspective view illustrating a reinforcing pin according to a sixth embodiment;

FIG. 13 is an exemplary perspective view illustrating a reinforcing pin according to a seventh embodiment;

FIG. 14 is an exemplary perspective view illustrating a reinforcing pin according to an eighth embodiment;

FIG. 15 is an exemplary perspective view illustrating a reinforcing pin according to a ninth embodiment;

FIG. 16 is an exemplary plan view illustrating an FPC and a relay connector according to a modification of the first embodiment; and

FIG. 17 is an exemplary plan view illustrating an FPC and a relay connector according to another modification of the first embodiment.

### DETAILED DESCRIPTION

In general, according to one embodiment, a connector includes a housing, a plurality of first leads, and a metal component. The first leads are attached to the housing in alignment with each other in a first direction. Each of the first leads includes a first external terminal outside the housing. The metal component is provided with a first opening and is attached to the housing. The metal component includes two first junction terminals being aligned with the first external terminals of the first leads in the first direction outside the housing. The first opening is located in-between the two first junction terminals.

### First Embodiment

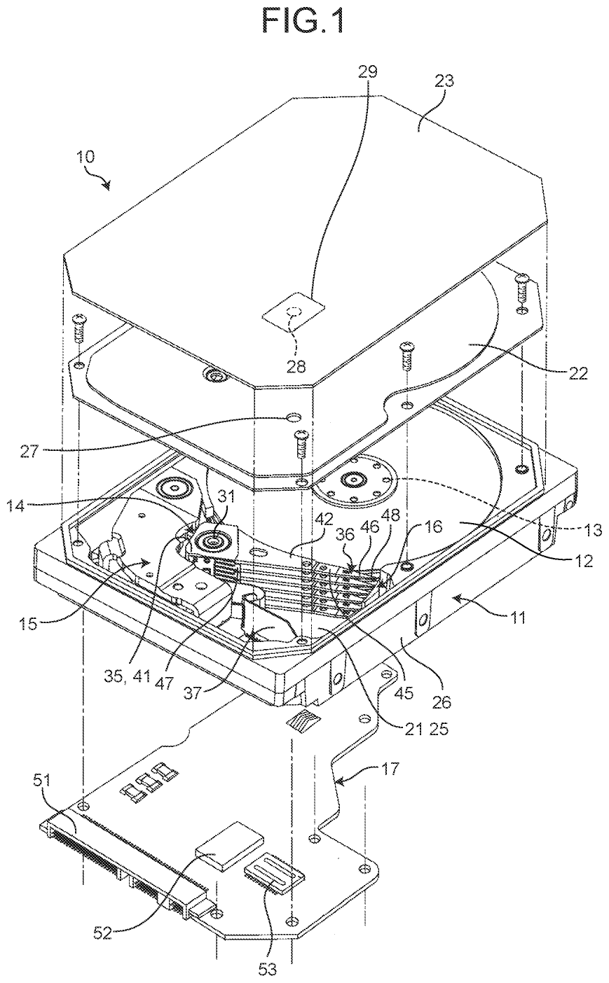

Hereinafter, a first embodiment will be described with reference to FIGS. 1 to 6. It is noted that, in the present specification, components according to embodiments and descriptions of the components may be described in a plurality of expressions. The components and the description thereof are examples, and are not limited by the expression of the present specification. Components may also be identified with names different from those described in the present specification. In addition, the components may be described by expressions different from the expressions in the present specification.

In the following description, “prevent” is defined as, for example, preventing occurrence of an event, an action, or an influence, or reducing a degree of the event, the action, or the influence.

FIG. 1 is an exemplary perspective view illustrating a hard disk drive (HDD) 10 according to a first embodiment in an exploded manner. The HDD 10 is an example of a disk device, and may also be referred to as an electronic device, a storage device, an external storage device, or a magnetic disk device. It is noted that the disk device is not limited to the HDD 10.

As illustrated in FIG. 1, the HDD 10 includes a case 11, a plurality of magnetic disks 12, a spindle motor 13, a head stack assembly (HSA) 14, a voice coil motor (VCM) 15, a ramp load mechanism 16, and a printed circuit board (PCB) 17. The magnetic disk 12 may also be referred to as a disk, a medium, or a platter.

The case 11 includes a base 21, an inner cover 22, and an outer cover 23. It is noted that the case 11 is not limited to this example. Each of the base 21, the inner cover 22, and the outer cover 23 is made of a metal material such as an aluminum alloy. It is noted that the materials of the base 21, the inner cover 22, and the outer cover 23 may be different from each other.

The base 21 is formed in a substantially rectangular parallelepiped box shape opened in one direction. The base 21 accommodates the plurality of magnetic disks 12, the spindle motor 13, the HSA 14, the VCM 15, and the ramp load mechanism 16.

The base 21 has a bottom wall 25 and a side wall 26. The bottom wall 25 is formed in a substantially rectangular (quadrangular) plate shape. The side wall 26 protrudes from an edge of the bottom wall 25 and is formed in a substantially rectangular frame shape.

The inner cover 22 is mounted on an end portion of the side wall 26 with, for example, a screw, and closes the base 21. The outer cover 23 covers the inner cover 22 and is mounted on the end portion of the side wall 26 by, for example, welding.

A vent hole 27 is provided in the inner cover 22. Furthermore, the outer cover 23 is provided with a vent hole 28. After components are mounted on the inside of the base 21, and the inner cover 22 and the outer cover 23 are mounted on the base 21, air inside the case 11 is removed from the vent holes 27 and 28. Furthermore, the inside of the case 11 is filled with gas different from air.

The gas filled inside the case 11 is, for example, a low density gas having a density lower than that of air, an inert gas having low reactivity, or the like. For example, helium is filled inside the case 11. It is noted that the inside of the case 11 may be filled with another fluid. The inside of the case 11 may be maintained at vacuum, low pressure close to vacuum, or negative pressure lower than atmospheric pressure.

The vent hole 28 of the outer cover 23 is closed by a seal 29. The seal 29 airtightly seals the vent hole 28 and restricts fluid filling the case 11 from leaking from the vent hole 28 to the outside of the case 11.

The plurality of magnetic disks 12 are formed in a disk shape arranged substantially parallel to the bottom wall. The plurality of magnetic disks 12 are arranged at intervals. The HDD 10 according to the present embodiment includes, for example, ten or more magnetic disks 12. It is noted that the number of magnetic disks 12 is not limited to this example.

The spindle motor 13 supports the plurality of magnetic disks 12. The plurality of magnetic disks 12 are held by a hub of the spindle motor 13 by, for example, a clamp spring. The spindle motor 13 rotates the plurality of magnetic disks 12.

The case 11 is provided with a support shaft 31 spaced apart from the magnetic disk 12. For example, the support shaft 31 extends from the bottom wall 25 of the case 11. The HSA 14 is rotatably supported by the support shaft 31.

The HSA 14 has a carriage 35, a plurality of head gimbal assemblies (HGA) 36, and a flexible printed circuit board (FPC) 37. The FPC is an example of a substrate. The carriage 35 includes an actuator block 41 and a plurality of arms 42.

The actuator block 41 and the plurality of arms 42 are integrally formed of, for example, aluminum and an alloy. It is noted that the materials of the actuator block 41 and the arm 42 are not limited to this example.

The actuator block 41 is supported by, for example, the support shaft 31 via a bearing so as to be rotatable around the support shaft 31. The plurality of arms 42 protrude substantially in parallel from the actuator block 41.

The plurality of arms 42 are arranged at intervals. Each of the plurality of arms 42 can enter a gap between two adjacent magnetic disks 12 among the plurality of magnetic disks 12.

The VCM 15 includes a voice coil mounted on the carriage 35, a pair of yokes, and magnets provided on the yokes. The VCM 15 rotates the carriage 35 around the support shaft 31.

Each of the plurality of HGAs 36 includes a base plate 45, a load beam 46, a flexure 47, and a magnetic head 48. The base plate 45 is mounted on the tip of the arm 42. The load beam 46 is formed to be thinner than the base plate 45 and extends from the base plate 45.

The flexure 47 is formed in an elongated belt shape. It is noted that the shape of the flexure 47 is not limited to this example. The flexure 47 is a kind of FPC including a metal plate (backing layer) made of stainless steel or the like, an insulating layer (base layer) formed on the metal plate, a conductive layer formed on the insulating layer and configured to form a plurality of wirings (wiring patterns), and an insulating layer (cover layer) covering the conductive layer.

A gimbal unit (elastic support unit) which is located on the load beam 46 and is displaceable is provided at one end portion of the flexure 47. The magnetic head 48 is mounted on the gimbal unit of the flexure 47. The magnetic head 48 records and reproduces information on a recording layer of the magnetic disk 12. In other words, the magnetic head 48 reads and writes information from and to the magnetic disk 12.

The VCM 15 rotates the carriage 35 to arrange the magnetic head 48 at a desired location on the magnetic disk 12. When the magnetic head 48 moves to the outermost periphery of the magnetic disk 12, the ramp load mechanism 16 holds the magnetic head 48 at an unload location spaced apart from the magnetic disk 12.

The FPC 37 is connected to the other end portion of the flexure 47. For example, a plurality of flexures 47 are connected to the FPC 37. Thus, the FPC 37 is electrically connected to the plurality of magnetic heads 48 via the wirings of the plurality of flexures 47.

The PCB 17 is, for example, a rigid substrate such as a glass epoxy substrate, and is a multilayer substrate or a build-up substrate. The PCB 17 is disposed outside the case 11 and is mounted on the bottom wall 25 of the base 21. The PCB 17 is mounted on the bottom wall 25 by, for example, a plurality of screws.

The HDD 10 further includes, for example, an interface (I/F) connector 51, a controller 52, and a relay connector 53. The I/F connector 51, the controller 52, and the relay connector 53 are mounted on the PCB 17. In addition, other components may be mounted on the PCB 17.

The I/F connector 51 is a connector conforming to an interface standard such as Serial ATA (SATA), and is connected to an I/F connector of a host computer. The controller 52 is, for example, a system-on-chip (SoC), and includes a read/write channel (RWC), a hard disk controller (HDC), and a processor.

The PCB 17 is electrically connected to various components disposed inside the case 11 through the relay connector 53. For example, the PCB 17 is electrically connected to the spindle motor 13, the VCM 15, the FPC 37, and the magnetic head 48.

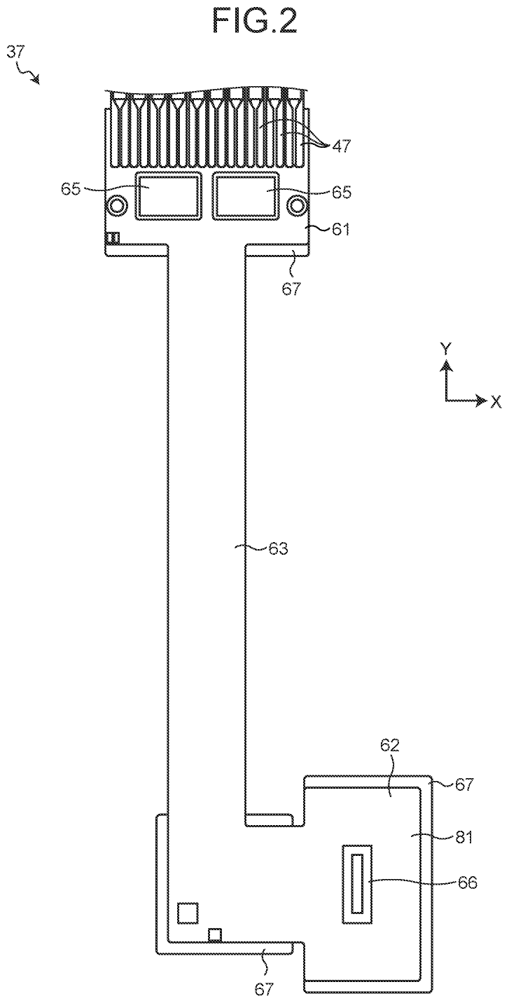

FIG. 2 is an exemplary plan view schematically illustrating the FPC 37 of the first embodiment. As illustrated in FIG. 2, the FPC 37 is detached from other components and is formed in a substantially L-shaped belt shape in a natural state in which no external force acts. It is noted that the shape of the FPC 37 is not limited to this example. The FPC 37 includes a first connection portion 61, a second connection portion 62, and an intermediate portion 63.

The first connection portion 61 is provided, for example, at one end portion of the FPC 37 in the direction in which the FPC 37 extends. The first connection portion 61 is mounted on the actuator block 41 by, for example, a screw. The first connection portion 61 is electrically connected to the flexure 47.

The second connection portion 62 is provided, for example, at the other end portion of the FPC 37 in the direction in which the FPC 37 extends. The second connection portion 62 is mounted on the bottom wall 25 by, for example, a screw. The second connection portion 62 is, for example, electrically connected to the relay connector 53 on the PCB 17.

The intermediate portion 63 is provided between the first connection portion 61 and the second connection portion 62. The intermediate portion 63 extends in a belt shape and bends between the first connection portion 61 and the second connection portion 62 in accordance with rotation of the actuator block 41.

As illustrated in the drawings, in the present specification, an X axis, a Y axis, and a Z axis are defined for convenience. The X axis, the Y axis, and the Z axis are orthogonal to each other. The X axis is provided along the width of the intermediate portion 63 in the natural state. The Y axis is provided along the length of the intermediate portion 63 in the natural state. The Z axis is provided along the thickness of the FPC 37 in the natural state.

Furthermore, in the present specification, an X direction, a Y direction, and a Z direction are defined. The X direction is a direction along the X axis and includes a +X direction indicated by an arrow of the X axis and a −X direction which is an opposite direction of the arrow of the X axis. The Y direction is a direction along the Y axis, and includes a +Y direction indicated by an arrow of the Y axis and a −Y direction which is an opposite direction of the arrow of the Y axis. The Z direction is a direction along the Z axis and includes a +Z direction indicated by an arrow of the Z axis and a −Z direction which is an opposite direction of the arrow of the Z axis.

The first connection portion 61 is connected to an end portion of the intermediate portion 63 in the +Y direction and extends in the +Y direction from the end portion. The second connection portion 62 is connected to an end portion of the intermediate portion 63 in the −Y direction and extends in the +X direction from the end portion. It is noted that the first connection portion 61 and the second connection portion 62 are not limited to this example.

The HDD 10 further includes a plurality of preamplifiers 65, a relay connector 66, and a plurality of reinforcing plates 67. The relay connector 66 is an example of a connector. The preamplifier 65 and the relay connector 66 are mounted on the FPC 37.

The preamplifier 65 is mounted on the first connection portion 61. The preamplifier 65 is electrically connected to the flexure 47 via, for example, wiring and pads of the FPC 37. The preamplifier 65 amplifies a write signal, transmits the write signal to the magnetic head 48, and amplifies a read signal received from the magnetic head 48.

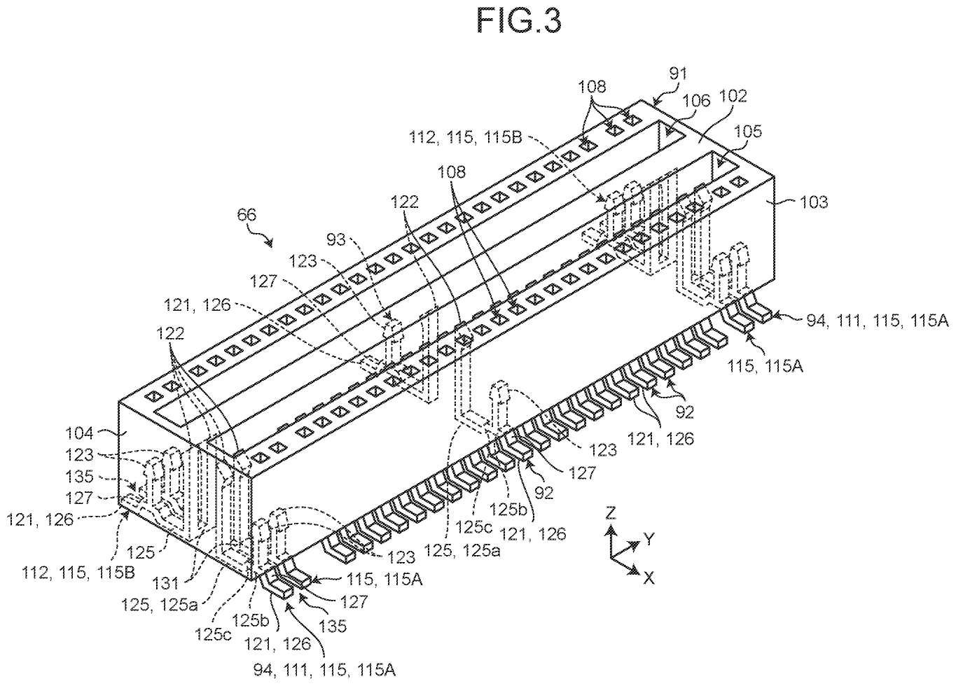

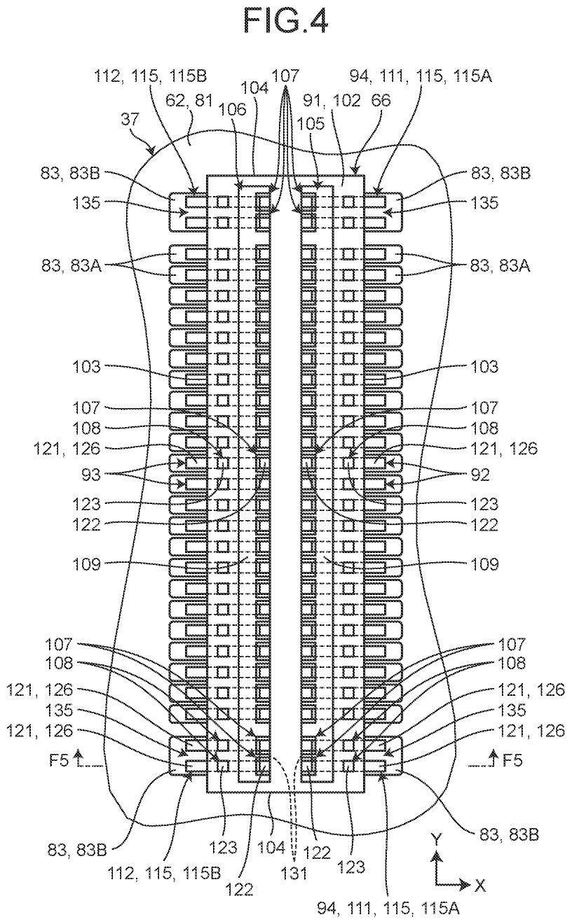

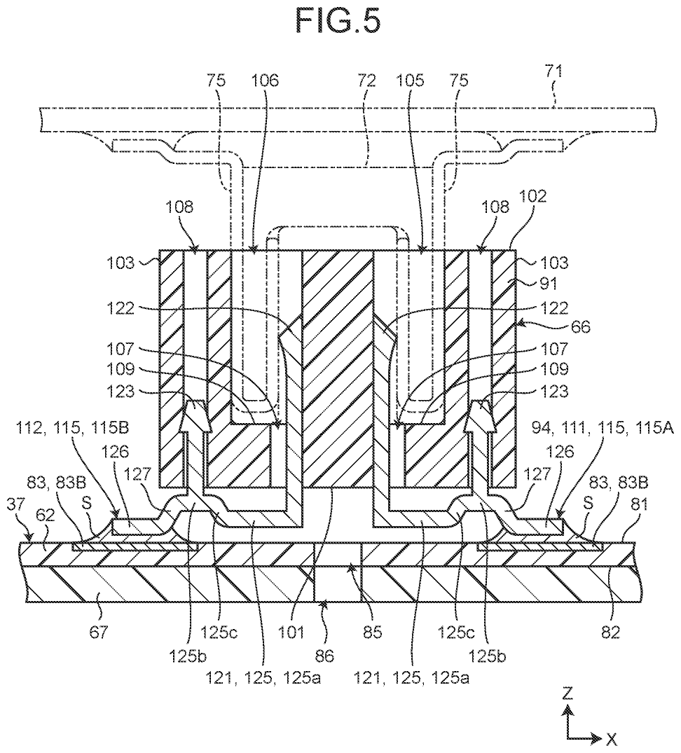

FIG. 3 is an exemplary perspective view illustrating the relay connector 66 of the first embodiment. FIG. 4 is an exemplary plan view illustrating the FPC 37 and the relay connector 66 of the first embodiment. FIG. 5 is an exemplary cross-sectional view of the FPC 37 and the relay connector 66 of the first embodiment taken along line F5-F5 in FIG. 4. As illustrated in FIG. 5, the relay connector 66 is mounted on the second connection portion 62.

The HDD 10 further includes a relay substrate 71 and a relay connector 72. The relay connector 72 is an example of a corresponding connector. For example, the relay substrate 71 is mounted on the bottom wall 25 so as to airtightly close a hole provided in the bottom wall 25. The relay connector 72 is mounted on the relay substrate 71 and is located inside the case 11. The relay connector 72 includes a plurality of leads 75.

The relay connector 72 on the relay substrate 71 and the relay connector 66 on the FPC 37 are connected to each other. Further, another relay connector located outside the case 11 is mounted on the relay substrate 71 and is connected to the relay connector 53 on the PCB 17. As a result, the relay connector 66 on the FPC 37 and the relay connector 53 on the PCB 17 are electrically connected to each other. It is noted that the relay connector 66 on the FPC 37 and the relay connector 53 on the PCB 17 may be directly connected to each other.

The reinforcing plate 67 is made of, for example, metal such as aluminum or synthetic resin, and is formed in a plate shape. It is noted that the reinforcing plate 67 is not limited to this example. As illustrated in FIG. 2, the plurality of reinforcing plates 67 are mounted on the first connection portion 61 and the second connection portion 62.

The reinforcing plate 67 has higher rigidity than that of the FPC 37. For this reason, the reinforcing plate 67 improves rigidity of the first connection portion 61 and the second connection portion 62. The intermediate portion 63 is not mounted on the reinforcing plate 67 and can be bent.

As illustrated in FIG. 5, the FPC 37 includes a mounting surface 81, a back surface 82, and a plurality of pads 83. The pad 83 may also be referred to as a land or an electrode. The mounting surface 81 is one surface of the FPC 37 and faces substantially in the +Z direction. The back surface 82 is located on the opposite side of the mounting surface 81 and is mounted on the reinforcing plate 67.

The plurality of pads 83 are provided on the mounting surface 81. The mounting surface 81 is formed by, for example, a part of the conductive layer forming the plurality of pads 83 and an insulating cover layer partially covering the conductive layer. It is noted that the mounting surface 81 is not limited to this example. As illustrated in FIG. 4, for example, the plurality of pads 83 are arranged in two rows in the Y direction.

At least one of the plurality of pads 83 is electrically connected to the preamplifier 65 via wiring of the conductive layer. It is noted that the pad 83 is not limited to this example. For example, at least one of the plurality of pads 83 may be electrically connected to the VCM 15 or a ground plane.

As illustrated in FIG. 5, a hole 85 is provided in the FPC 37. The hole 85 is located between the plurality of pads 83 forming one row and the plurality of pads 83 forming the other row in the X direction. The hole 85 penetrates the FPC 37 and opens to the mounting surface 81 and the back surface 82. The reinforcing plate 67 is also provided with a hole 86. The hole 86 penetrates the reinforcing plate 67 and communicates with the hole 85 of the FPC 37.

As illustrated in FIG. 4, the relay connector 66 includes a housing 91, a plurality of leads 92 and 93, and two reinforcing components 94. The leads 92 and 93 may also be referred to as terminals. The plurality of leads 92 are an example of a plurality of first leads. The plurality of leads 93 are an example of a plurality of second leads. The reinforcing component 94 is an example of a metal component.

The housing 91 is made of, for example, synthetic resin. The housing 91 is formed in a substantially rectangular parallelepiped shape extending in the Y direction. That is, the Y direction is the longitudinal direction of the housing 91. It is noted that the shape of the housing 91 is not limited to this example. The housing 91 has a lower surface 101, an upper surface 102, and two side surfaces 103 illustrated in FIG. 5, and two end surfaces 104 illustrated in FIG. 4.

Each of the lower surface 101, the upper surface 102, and the two side surfaces 103 is formed in a substantially rectangular shape extending in the Y direction which is the longitudinal direction. It is noted that the shapes of the lower surface 101, the upper surface 102, and the side surfaces 103 are not limited to this example.

As illustrated in FIG. 5, the lower surface 101 is formed to be substantially flat and faces substantially in the −Z direction. It is noted that the lower surface 101 may be provided with irregularities. The lower surface 101 of the housing 91 and the mounting surface 81 of the FPC 37 face each other with a gap interposed therebetween. Therefore, the housing 91 is spaced apart from the FPC 37. It is noted that the housing 91 may be in contact with the FPC 37. The lower surface 101 faces the hole 85 of the FPC 37.

The upper surface 102 is located on the opposite side of the lower surface 101. The upper surface 102 is formed to be substantially flat and faces substantially in the +Z direction. The two side surfaces 103 are respectively provided at the opposite ends of the housing 91 in the X direction, and are formed to be substantially flat. As illustrated in FIG. 4, the two end surfaces 104 are respectively provided at the opposite ends of the housing 91 in the Y direction, and are formed to be substantially flat.

The housing 91 is provided with two concave portions 105 and 106, a plurality of insertion holes 107, and a plurality of fixing holes 108. The two concave portions 105 and 106 are adjacent to each other in the X direction and open to the upper surface 102. Each of the two concave portions 105 and 106 extends in the Y direction. The two concave portions 105 and 106 may be spaced apart from each other or may communicate with each other.

The housing 91 further has two bottom surfaces 109. One of the two bottom surfaces 109 is provided at an end portion of the concave portion 105 in the −Z direction. The other of the two bottom surfaces 109 is provided at an end portion of the concave portion 106 in the −Z direction. The two bottom surfaces 109 are formed to be substantially flat and face substantially in the +Z direction.

Each of the plurality of insertion holes 107 penetrates the housing 91 substantially in the Z direction so as to open to the lower surface 101 and the bottom surface 109. Half of the plurality of insertion holes 107 are arranged at intervals in the Y direction and communicate with the concave portion 105. The other half of the plurality of insertion holes 107 are arranged at intervals in the Y direction and communicate with the concave portion 106. That is, the plurality of insertion holes 107 are arranged in two rows in the Y direction.

Each of the plurality of fixing holes 108 penetrates the housing 91 substantially in the Z direction so as to open to the lower surface 101 and the upper surface 102. The plurality of fixing holes 108 are arranged in two rows in the Y direction. The two concave portions 105 and 106 are located between the plurality of fixing holes 108 forming one row and the plurality of fixing holes 108 forming the other row in the X direction.

The cross section of each of the plurality of insertion holes 107 and the plurality of fixing holes 108 is smaller than the cross section of the concave portions 105 and 106. In the present embodiment, the cross section of each of the insertion hole 107 and the fixing hole 108 is formed in a square or a perfect circular shape. It is noted that the cross section of each of the insertion hole 107 and the fixing hole 108 is not limited to this example.

The plurality of leads 92 and 93 and the two reinforcing components 94 are made of metal. It is noted that the materials of the leads 92 and 93 and the reinforcing component 94 may be different from each other. The plurality of leads 92 and the plurality of leads 93 are adjacent to each other in the X direction and are formed in mirror symmetry with each other.

In the first embodiment, each of the two reinforcing components 94 has two reinforcing pins 111 and 112. The two reinforcing pins 111 and 112 are adjacent to each other in the X direction and are formed in mirror symmetry with each other.

As illustrated in FIG. 3, each of the reinforcing pins 111 and 112 has two lead-like members 115. The lead-like member 115 of the reinforcing pin 111 is referred to as a lead-like member 115A. Further, the lead-like member 115 of the reinforcing pin 112 is referred to as a lead-like member 115B.

The leads 92 and 93 and the lead-like member 115 are an example of the lead. The lead-like member 115A is an example of a lead-like member and a first lead-like member. The lead-like member 115B is an example of a second lead-like member. The lead-like members 115, 115A and 115B may also be referred to as dummy leads, ground leads, non-transmission leads, metal pieces, or metal leads.

The lead-like member 115A and the lead 92 have a common shape. The lead-like member 115B and the lead 93 have a common shape. The lead-like member 115A and the lead-like member 115B are adjacent to each other in the X direction and are formed in mirror symmetry with each other.

Hereinafter, the leads 92 and 93 and the lead-like member 115 will be described with reference to FIGS. 4 and 5. FIG. 5 illustrates the lead-like member 115. However, the leads 92 and 93 and the lead-like member 115 have a common shape or a mirror-symmetrical shape. For this reason, the leads 92 and 93 and the lead-like member 115 can be understood from FIG. 5 and the following description of the lead-like member 115.

As illustrated in FIG. 5, each of the plurality of leads 92 and 93 and the plurality of lead-like members 115 includes an external pin 121, an internal pin 122, and a press-fit pin 123. Therefore, each of the reinforcing pins 111 and 112 includes two external pins 121, two internal pins 122, and two press-fit pins 123. It is noted that the number of each of the external pins 121, the internal pins 122, and the press-fit pins 123 in each of the reinforcing pins 111 and 112 may be three or more.

The external pin 121 of the lead 92 is an example of a first external terminal and an external terminal. The external pin 121 of the lead 93 is an example of a second external terminal and an external terminal. The internal pin 122 of the lead 92 is an example of a first internal terminal. The internal pin 122 of the lead 93 is an example of a second internal terminal.

The external pin 121 of the lead-like member 115A is an example of a first junction terminal. The external pin 121 of the lead-like member 115B is an example of a second junction terminal. The internal pin 122 of the lead-like member 115A is an example of a first terminal-like part. The internal pin 122 of the lead-like member 115B is an example of a second terminal-like part.

The external pin 121 is located outside the housing 91. Specifically, the external pin 121 is located outside the concave portions 105 and 106 and the insertion hole 107, and is located at least partially between the housing 91 and the FPC 37. Therefore, the lower surface 101 of the housing 91 faces the external pin 121. It is noted that a part of the external pin 121 may be located inside the housing 91.

The external pin 121 includes a base portion 125, a joining portion 126, and an inclined portion 127. The entire base portion 125 is located between the housing 91 and the FPC 37. It is noted that the base portion 125 is not limited to this example.

The base portion 125 includes a first connection portion 125a, a second connection portion 125b, and an intermediate portion 125c. The first connection portion 125a and the second connection portion 125b extend substantially in the X direction. That is, the first connection portion 125a and the second connection portion 125b extend along the lower surface 101 of the housing 91.

The first connection portion 125a is closer to the insertion hole 107 than the second connection portion 125b. The second connection portion 125b is closer to the fixing hole 108 than the first connection portion 125a. Furthermore, the first connection portion 125a is spaced apart from the lower surface 101 of the housing 91 more than the second connection portion 125b. That is, the first connection portion 125a and the second connection portion 125b extend substantially in parallel. The intermediate portion 125c extends obliquely with respect to the first connection portion 125a and the second connection portion 125b between one end of the first connection portion 125a and one end of the second connection portion 125b.

The joining portion 126 is spaced apart from the housing 91 more than the second connection portion 125b of the base portion 125. Specifically, the joining portion 126 is spaced apart from the center of the housing 91 more than the second connection portion 125b in the X direction. Further, the joining portion 126 is spaced apart from the housing 91 more than the first connection portion 125a in the Z direction. The joining portion 126 is located at an end portion of the relay connector 66 in the −Z direction.

The joining portion 126 extends substantially in the X direction. Therefore, the joining portion 126 and the first connection portion 125a and the second connection portion 125b of the base portion 125 extend substantially in parallel. The inclined portion 127 is provided between the other end portion of the second connection portion 125b and one end portion of the joining portion 126, and extends obliquely with respect to the second connection portion 125b and the joining portion 126.

As illustrated in FIG. 4, in a projection view seen in a direction orthogonal to the upper surface 102 (in the −Z direction in FIG. 4), the external pin 121 extends across the side surface 103. For example, in the projection view viewed in the direction orthogonal to the upper surface 102, the joining portion 126 is spaced apart from the housing 91.

As illustrated in FIG. 5, the internal pin 122 protrudes substantially in the +Z direction from the other end portion of the first connection portion 125a. In other words, the internal pin 122 and the first connection portion 125a are connected to each other.

As illustrated in FIG. 4, the plurality of leads 92 and the internal pin 122 of the lead-like member 115A are accommodated in the concave portion 105 and the plurality of insertion holes 107. The plurality of leads 93 and the internal pin 122 of the lead-like member 115B are accommodated in the concave portion 106 and the plurality of insertion holes 107. That is, the internal pin 122 is located inside the housing 91. The internal pin 122 passes through the insertion hole 107.

As illustrated in FIG. 5, the press-fit pin 123 protrudes substantially in the +Z direction from the second connection portion 125b. That is, the press-fit pin 123 protrudes from the base portion 125 at a location spaced apart from the internal pin 122. The internal pin 122 and the press-fit pin 123 protrude substantially in parallel from the base portion 125.

The press-fit pin 123 is press-fitted into the fixing hole 108. As a result, the leads 92 and 93 and the reinforcing component 94 are mounted in the housing 91. It is noted that the leads 92 and 93 and the reinforcing component 94 may be mounted in the housing 91 by other methods.

The leads 92 and the press-fit pins 123 of the lead-like member 115A are press-fitted into the fixing holes 108 forming one row such that the plurality of leads 92 and the two reinforcing components 94 are arranged at intervals in the Y direction. Accordingly, the external pins 121 of the plurality of leads 92 and the external pins 121 of the lead-like member 115A are arranged at intervals in the Y direction. The Y direction is an example of the first direction.

The leads 93 and the press-fit pins 123 of the lead-like member 115B are press-fitted into the fixing holes 108 forming the other row such that the plurality of leads 93 and the two reinforcing components 94 are arranged at intervals in the Y direction. Accordingly, the external pins 121 of the plurality of leads 93 and the external pins 121 of the lead-like member 115B are arranged at intervals in the Y direction.

As illustrated in FIG. 4, the plurality of leads 93 are spaced apart from the plurality of leads 92 in the −X direction. The −X direction is an example of a second direction. In the present embodiment, each of the plurality of leads 93 is disposed at substantially the same location as a corresponding one of the plurality of leads 92 in the Y direction.

The reinforcing pin 112 is spaced apart from the reinforcing pin 111 in the −X direction. In the present embodiment, each of the plurality of lead-like members 115B is disposed at substantially the same location as a corresponding one of the plurality of lead-like members 115A in the Y direction. The leads 92 and 93 and the external pins 121 of the reinforcing component 94 are arranged in two rows in the Y direction.

The plurality of leads 92 are located between the reinforcing pins 111 of the two reinforcing components 94. Therefore, one of the two external pins 121 of the reinforcing pin 111 is located at an end of a row formed by the external pins 121 of the plurality of leads 92 and the external pins 121 of the reinforcing component 94.

The plurality of leads 93 are located between the reinforcing pins 112 of the two reinforcing components 94. Therefore, one of the two external pins 121 of the reinforcing pin 112 is located at an end of a row formed by the external pins 121 of the plurality of leads 93 and the external pins 121 of the reinforcing component 94. That is, the external pins 121 of the reinforcing component 94 are respectively disposed at four corners of the reinforcing pins 111 arranged in two rows. It is noted that the locations of the leads 92 and 93 and the reinforcing component 94 are not limited to the above example.

As illustrated in FIG. 5, the external pin 121 is joined to the plurality of pads 83 by, for example, solder S. As a result, the relay connector 66 is mounted on the FPC 37. The external pins 121 of the leads 92 and 93 are electrically connected to, for example, the preamplifier 65 via the wiring of the FPC 37.

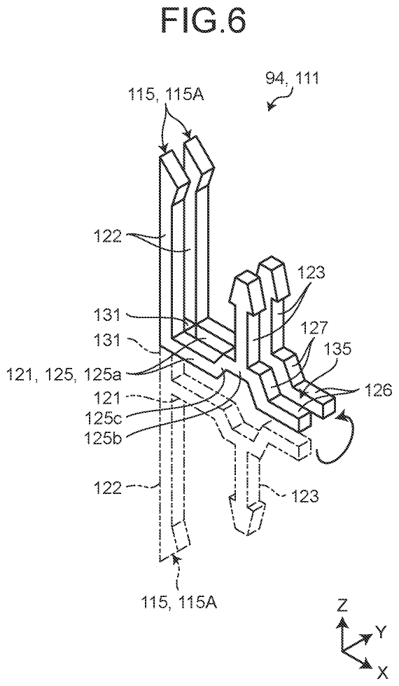

FIG. 6 is an exemplary perspective view illustrating the reinforcing pin 111 of the first embodiment. As illustrated in FIG. 6, in each of the reinforcing pins 111 and 112, the two lead-like members 115 are arranged at intervals in the Y direction. Therefore, in each of the reinforcing pins 111 and 112, the external pins 121 of the two lead-like members 115 are arranged at intervals in the Y direction. The external pins 121 of the two lead-like members 115 have a common shape or a mirror-symmetrical shape.

Each of the reinforcing pins 111 and 112 further includes a coupling part 131. The coupling part 131 of the reinforcing pin 111 is an example of a first coupling part and a coupling part. The coupling part 131 of the reinforcing pin 112 is an example of a fourth coupling part.

In each of the reinforcing pins 111 and 112, the coupling part 131 couples the two external pins 121 to each other. In other words, the coupling part 131 couples the two adjacent lead-like members 115 to each other.

In the present embodiment, the coupling part 131 is connected to the external pins 121 at a location where the internal pin 122 and the first connection portion 125a are connected to each other. The coupling part 131 extends in the Y direction between the two external pins 121. It is noted that the location of the coupling part 131 is not limited to this example.

A slit 135 is provided between the external pins 121 of the two lead-like members 115. The slit 135 of the reinforcing pin 111 is an example of a first opening. The slit 135 of the reinforcing pin 112 is an example of a second opening.

The slit 135 is a gap between the two external pins 121 arranged in the Y direction. The slit 135 may communicate with a gap between the two internal pins 122 arranged in the Y direction, or may communicate with a gap between the two press-fit pins 123 arranged in the Y direction.

An interval between the external pins 121 of the two lead-like members 115A is shorter than or equal to an interval between the external pins 121 of the plurality of leads 92. Further, an interval between the external pins 121 of the two lead-like members 115B is shorter than or equal to an interval between the external pins 121 of the plurality of leads 93. Therefore, a width of the slit 135 is equal to or less than a width of an interval between the external pins 121 of the plurality of leads 92 and 93.

As illustrated in FIGS. 3 and 6, the external pins 121 of the lead-like member 115A and the external pins 121 of the lead 92 have a common shape. The external pins 121 of the lead-like member 115B and the external pins 121 of the lead 93 have a common shape. The external pins 121 of the lead-like member 115A and the external pins 121 of the lead-like member 115B have a common shape or a mirror-symmetrical shape.

The internal pins 122 of the lead-like member 115A and the internal pins 122 of the lead 92 have a common shape. The internal pins 122 of the lead-like member 115B and the internal pins 122 of the lead 93 have a common shape.

The leads 92 and 93 and the lead-like member 115 may not be completely identical as long as the shapes described above are common. For example, there may be a difference between the leads 92 and 93 and the lead-like member 115 due to the reinforcing pins 111 and 112 having the coupling part 131.

As illustrated in FIG. 4, the plurality of pads 83 includes a plurality of pads 83A and four pads 83B. The pad 83A is an example of a first pad. The pad 83B is an example of a second pad.

Half of the plurality of pads 83A are located between two of the four pads 83B and are arranged at intervals in the Y direction. The other half of the plurality of pads 83A are located between the other two of the four pads 83B and are arranged at intervals in the Y direction.

The external pins 121 of the leads 92 and 93 are joined to the pads 83A by the solder S. The external pins 121 of the reinforcing component 94 are joined to the pads 83B by the solder S. Two external pins 121 respectively included in the reinforcing pins 111 and 112 are respectively joined to the pads 83B. In other words, two external pins 121 spaced apart from each other are respectively joined to the pads 83B. The size of each of the pads 83B is larger than the size of each of the pads 83A.

The plurality of pads 83A are used, for example, for signal transmission between the controller 52 and the preamplifier 65. For example, at least one of the plurality of pads 83A is connected to a signal terminal or a power supply terminal of the preamplifier 65 via wiring. At least one of the plurality of pads 83A may be electrically connected to the ground.

For example, the four pads 83B are electrically connected to the ground. In other words, the pads 83B are set to a ground potential. It is noted that the pads 83B are not limited to this example, and may be, for example, floating independent of other wirings. For example, since the pads 83B are floating, flexibility of a wiring design in the vicinity of the relay connector 66 is improved.

When the relay connectors 66 and 72 are connected to each other as illustrated in FIG. 5, the internal pins 122 of the leads 92 and 93 and the reinforcing component 94 and the lead 75 of the relay connector 72 come into contact with each other. As a result, the internal pins 122 and the lead 75 are electrically connected to each other.

The lead 75 electrically connected to the internal pins 122 of the reinforcing component 94 is electrically connected to the ground and is set to the ground potential. The lead 75 electrically connected to the reinforcing component 94 is an example of a ground terminal.

The relay connector 72 may not have the lead 75 electrically connected to the reinforcing component 94. In this case, the internal pins 122 of the reinforcing component 94 may be covered with the housing 91 without being accommodated in the concave portions 105 and 106.

Hereinafter, a part of a method of mounting the relay connector 66 on the FPC 37 will be exemplified. It is noted that the method of mounting the relay connector 66 on the FPC 37 is not limited to the following method, and other methods may be used. First, solder paste (solder S) is supplied to the pad 83 by, for example, printing or coating. Further, the relay connector 66 is mounted on the pad 83.

Next, the FPC 37 is heated in a reflow furnace, and the solder paste is melted. As a result, the joining portion 126 of the relay connector 66 is joined to the pad 83. At this time, flux mixed or separately supplied to the solder S may flow out of the solder S.

The solder paste adheres to the joining portion 126 of the external pin 121. When the solder paste is melted, the solder S and the flux spread along the external pin 121. For example, the flux may spread from the joining portion 126 along the inclined portion 127 toward the base portion 125.

In the reinforcing component 94, the slit 135 is provided between the two external pins 121. The flux flows into the slit 135. The flux adheres to the two external pins 121 in the slit 135 and remains in the slit 135 due to, for example, surface tension. That is, the reinforcing component 94 can prevent the flux from further spreading by holding the flux in the slit 135.

Next, the FPC 37 and the relay connector 66 are cleaned by, for example, ultrasonic cleaning. For example, the FPC 37 is placed in a tank filled with a cleaning liquid. For example, the cleaning liquid flows into a gap between the FPC 37 and the housing 91 and flows out from the holes 85 and 86. Further, the cleaning liquid passes through the slit 135. The cleaning liquid removes substances that may contaminate the HDD 10, such as flux. When the ultrasonic cleaning is completed, the FPC 37 is taken out from the cleaning liquid.

For example, the cleaning liquid transmits ultrasonic waves. The ultrasonic waves float the flux. Thereafter, the cleaning liquid is discharged together with the flux as described above. As described above, the mounting of the relay connector 66 on the FPC 37 is completed.

Hereinafter, a part of the method of manufacturing the reinforcing pins 111 and 112 will be exemplified. It is noted that the method of manufacturing the reinforcing pins 111 and 112 is not limited to the following method, and other methods may be used. As indicated by a two-dot chain line in FIG. 6, the two lead-like members 115 are manufactured by, for example, die casting so as to be arranged in the Z direction in mirror symmetry. At this time, the coupling part 131 extends substantially in the Z direction between the two lead-like members 115, and couples the two lead-like members 115 manufactured by the die casting to each other.

Next, as indicated by an arrow in FIG. 6, a portion at which one lead-like member 115 and the coupling part 131 are connected, the portion being indicated by a two-dot chain line, is bent, and a portion at which the other lead-like member 115 and the coupling part 131 are connected, the portion being indicated by a solid line, is further bent. Accordingly, as indicated by the solid line in FIG. 6, the reinforcing pins 111 and 112 in which the two lead-like members 115 are arranged in the Y direction are manufactured.

The leads 92 and 93 and the reinforcing pins 111 and 112 can be manufactured by the identical mold. For example, the two lead-like members 115 manufactured by die casting are spaced apart from the coupling part 131. The lead-like members 115 spaced apart from the coupling part 131 serve as the leads 92 and 93, respectively. The coupling part 131 is, for example, a runner for manufacturing the leads 92 and 93 by die casting.

In the HDD 10 according to the first embodiment described above, each of the plurality of leads 92 includes the external pin 121 outside the housing 91. The plurality of leads 92 are attached to the housing 91 in alignment with each other in the Y direction. The reinforcing component 94 is attached to the housing 91, which includes two external pins 121 of the reinforcing pin 111 which are juxtaposed to each other in the Y direction outside the housing 91. The external pins 121 of the plurality of leads 92 and the two external pins 121 of the reinforcing pin 111 are aligned with each other in the Y direction. The slit 135 extends between the two external pins 121 of the reinforcing pin 111. The lead 92 and the external pins 121 of the reinforcing pin 111 are juxtaposed to each other in the Y direction so that they can be joined together to the pad 83 of the FPC 37 with, for example, the solder S. Generally, flux is mixed with or separately added to the solder S. Such flux may run up the external pin 121 toward the housing 91. According to the first embodiment, however, the flux can be accumulated in the slit 135 extending between the two external pins 121 of the reinforcing pin 111 due to, for example, surface tension. Namely, the reinforcing component 94 can prevent or restrict the flux from entering the inside of the housing 91 along the reinforcing component 94. The flux remnant outside the housing 91 is easily removable by cleaning. In this manner, the relay connector 66 of the present embodiment can be avoided from being internally contaminated by a remnant substance such as flux. In addition, the relay connector 66 of the present embodiment can be more firmly attached to the FPC 37 by joining the reinforcing component 94 to the pad 83 in addition to the lead 92.

The reinforcing component 94 includes the coupling part 131 that couples the two external pins 121 of the reinforcing pin 111 to each other. Accordingly, the reinforcing component 94 can be improved in strength. In addition, the reinforcing component 94 has a larger surface area to which the solder S adheres, so that it can be more firmly attached to the FPC 37.

The two external pins 121 of the reinforcing pin 111 have a same shape or are mirror-symmetric to each other. The reinforcing pin 111 can be manufactured, for example, by bending the two external pins 121 of the same or mirror-symmetric shape with respect to the coupling part 131. The reinforcing component 94 can thus be easily manufactured.

The reinforcing pin 111 includes two lead-like members 115A each of has one of the two external pins 121. The plurality of leads 92 and the two lead-like members 115A have a same shape. As such, the reinforcing pin 111 and the lead 92 can be formed using, for example, the same mold, thereby facilitating the manufacture of the reinforcing pin 111. In addition, the reinforcing pin 111 and the lead 92 can be attached to the housing 91 in the same manner, thus, the reinforcing pin 111 is easily attachable to the housing 91.

Each of the plurality of leads 93 includes the external pin 121 outside the housing 91. The plurality of leads 93 are attached to the housing 91 in alignment with each other in the Y direction, and spaced from the plurality of leads 92 in the −X direction intersecting the Y direction. The reinforcing pin 112 of the reinforcing component 94 includes two external pins 121 and the coupling part 131. The two external pins 121 of the reinforcing pin 112 are juxtaposed to each other in the Y direction outside the housing 91. The coupling part 131 of the reinforcing pin 112 couples the two external pins 121 to each other. The external pins 121 of the plurality of leads 93 and the two external pins 121 of the reinforcing pin 112 are mutually aligned in the Y direction. The slit 135 extends between the two external pins 121 of the reinforcing pin 112. The plurality of leads 93 and the external pins 121 of the reinforcing pin 112 are aligned in the Y direction, therefore, they can be joined together to the pad 83 of the FPC 37 using, for example, the solder S. Flux can be accumulated in the slit 135 extending between the two external pins 121 due to, for example, surface tension. Namely, the reinforcing component 94 can avoid or restrict the flux from entering the inside of the housing 91 along the reinforcing pin 112. Thus, the relay connector 66 of the present embodiment can be prevented from being internally contaminated by a remnant substance such as flux. Furthermore, the reinforcing component 94 can be improved in strength and more firmly attached to the FPC 37.

The two external pins 121 of the reinforcing pin 111 and the two external pins 121 of the reinforcing pin 112 have a same shape or are mirror-symmetric. Thus, the reinforcing pin 111 having the two external pins 121 and the coupling part 131 and the reinforcing pin 112 having the two external pins 121 and the coupling part 131 can be designed in the same shape. This can facilitate the manufacture of the reinforcing component 94 and the attachment thereof to the housing 91.

The interval between the two external pins 121 of the reinforcing pin 111 is shorter than or equal to the intervals among the plurality of leads 92. As a result, the slit 135 in the relay connector 66 of the present embodiment cannot be extended in width to be able to surely hold the flux.

One of the two external pins 121 of the reinforcing pin 111 is located at an end of a row of the external pins 121 of the plurality of leads 92 and the two external pins 121 of the reinforcing pin 111. For example, the relay connector 66 may be offset from a desired position in a rotational direction around the center of the relay connector 66. In this case, the relay connector 66 may receive a rotational force around the center when connected to the relay connector 72. The external pins 121 of the reinforcing pin 111 are spaced further apart from the center of the relay connector 66 than the ones located at the center of the row. Because of this, the external pins 121 of the reinforcing pin 111 can more effectively exert a larger force for coupling the relay connector 66 to the FPC 37 against the rotational force around the center of the relay connector 66.

The FPC 37 includes a plurality of pads 83A to which the external pins 121 of the plurality of leads 92 are joined, and one pad 83B to which the two external pins 121 of the reinforcing component 94 are joined. Thus, the two external pins 121 of the reinforcing component 94 are joined to the same pad 83B. This can facilitate the attachment of the two external pins 121 of the reinforcing component 94 to the FPC 37. In addition, due to presence of the solder S between the two external pins 121 of the reinforcing component 94, the slit 135 can easily hold the flux.

The pad 83B is set to the ground potential. As a result, in a situation that receiving electromagnetic waves, the reinforcing component 94 has current flowing therethrough, for example, the current is absorbed by the ground. As such, the reinforcing component 94 can reduce influences on the transmission characteristics of the peripheral components, such as crosstalk.

The relay connector 72 includes the lead 75 electrically connected to the reinforcing component 94 and set to a ground potential. The reinforcing component 94 thus has the ground potential. In a situation that receiving electromagnetic waves, the reinforcing component 94 has current flowing therethrough, for example, the current is absorbed by the ground. In this manner, the reinforcing component 94 can reduce influences on the transmission characteristics in the peripheral components, such as crosstalk.

Each of the leads 92 and 93 and the lead-like member 115 includes the external pin 121 outside the housing 91. The leads 92 and 93 and the lead-like member 115 have the same shape and are attached to the housing 91 in two rows in the Y direction. The coupling part 131 couples the leads 92 and 93 and two adjacent lead-like members 115 to each other among the lead-like members 115. The leads 92 and 93 and the lead-like members 115 can be joined to the pad 83 of the FPC 37 using, for example, the solder S. Flux can be accumulated in the slit 135 between the two lead-like members 115 due to, for example, surface tension. Thus, the lead-like members 115 can prevent or restrict the flux from entering the housing 91 along the lead-like members 115. Consequently, the relay connector 66 of the present embodiment can be avoided from being internally contaminated by a remnant substance such as flux. Further, being mutually coupled by the coupling part 131, the two lead-like members 115 can be improved in strength and more firmly attached to the FPC 37.

### Second Embodiment

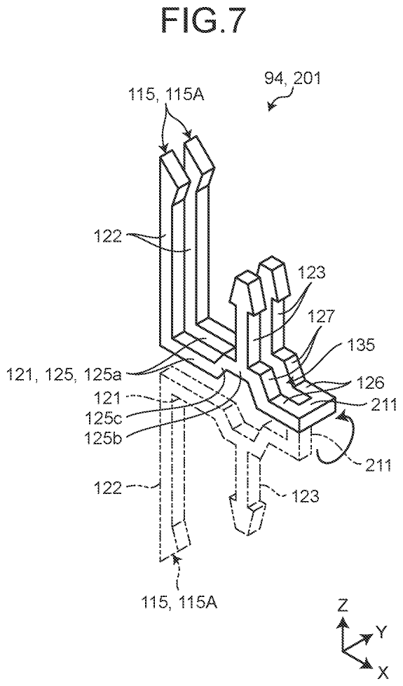

Hereinafter, a second embodiment will be described with reference to FIG. 7. It is noted that in the following description of the plurality of embodiments, components having functions similar to those of components already described are denoted by the same reference numerals as those of the components already described, and the description thereof may be omitted. In addition, the plurality of components denoted by the same reference numerals do not necessarily have all the functions and properties in common, and may have different functions and properties according to each embodiment.

FIG. 7 is an exemplary perspective view illustrating a reinforcing pin 201 according to the second embodiment. It is noted that a reinforcing pin indicated by a two-dot chain line in the drawings of FIG. 7 and subsequent drawings indicates that the reinforcing pin can be manufactured by bending a portion at which the lead-like member 115 and the coupling part are connected, similarly to the reinforcing pins 111 and 112 of the first embodiment.

As illustrated in FIG. 7, the reinforcing component 94 of the second embodiment has the reinforcing pin 201 instead of the reinforcing pins 111 and 112. The reinforcing pin 201 is substantially equal to the reinforcing pins 111 and 112, except as described below.

The reinforcing pin 201 has a coupling part 211 instead of the coupling part 131. The coupling part 211 is an example of a first coupling part and a fourth coupling part. The coupling part 211 couples the two external pins 121 to each other.

The coupling part 211 is connected to the external pin 121 at an end portion of the joining portion 126 spaced apart from the inclined portion 127. In other words, the coupling part 211 couples end portions in the X direction of the two external pins 121 to each other. The coupling part 211 extends in the Y direction between the two external pins 121. The coupling part 211 is spaced apart from the housing 91.

In the HDD 10 of the second embodiment described above, the coupling part 211 is spaced apart from the housing 91. Therefore, the flux can remain to be spaced apart from the housing 91 due to, for example, surface tension. Therefore, the relay connector 66 of the present embodiment can be avoided from being internally contaminated by a remnant substance such as flux.

### Third Embodiment

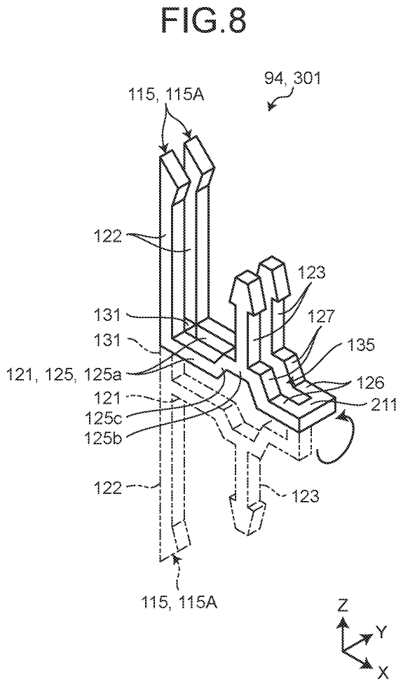

Hereinafter, a third embodiment will be described with reference to FIG. 8. FIG. 8 is an exemplary perspective view illustrating a reinforcing pin 301 according to the third embodiment. As illustrated in FIG. 8, the reinforcing component 94 of the third embodiment has the reinforcing pin 301 instead of the reinforcing pins 111 and 112. The reinforcing pin 301 is substantially equal to the reinforcing pins 111 and 112, except as described below.

The reinforcing pin 301 has the coupling part 131 of the first embodiment and the coupling part 211 of the second embodiment. The coupling part 211 is an example of a second coupling part. The slit 135 is located between the two coupling parts 131 and 211.

In the HDD 10 of the third embodiment described above, the reinforcing component 94 has the coupling part 211 that couples the two external pins 121 to each other. The slit 135 is located between the coupling part 131 and the coupling part 211. As a result, the reinforcing component 94 can be improved in strength to be more firmly attached to the FPC 37. Furthermore, the coupling part 131 can block flux moving toward the housing 91 due to, for example, a capillary phenomenon in the slit 135. Therefore, the reinforcing component 94 can prevent or restrict the flux from entering the inside of the housing 91 along the reinforcing component 94.

### Fourth Embodiment

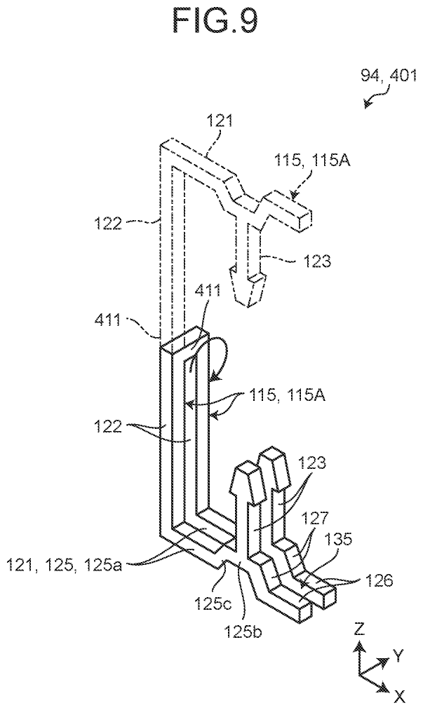

Hereinafter, a fourth embodiment will be described with reference to FIG. 9. FIG. 9 is an exemplary perspective view illustrating a reinforcing pin 401 according to the fourth embodiment. As illustrated in FIG. 9, the reinforcing component 94 of the fourth embodiment has the reinforcing pin 401 instead of the reinforcing pins 111 and 112. The reinforcing pin 401 is substantially equal to the reinforcing pins 111 and 112, except as described below.

The reinforcing pin 401 has a coupling part 411 instead of the coupling part 131. The coupling part 411 is an example of a third coupling part and a fifth coupling part. The coupling part 411 couples the two internal pins 122 to each other.

For example, the coupling part 411 is connected to the internal pins 122 at end portions of the internal pins 122 spaced apart from the first connection portion 125a. The coupling part 411 extends in the Y direction between the two internal pins 122.

In the HDD 10 of the fourth embodiment described above, each of the plurality of leads 92 has the internal pins 122 located inside the housing 91 and connected to the external pins 121. The two external pins 121 of the reinforcing pin 401 have a same shape as the external pins 121 of the lead 92. The reinforcing pin 401 has two internal pins 122 and the coupling part 411. The two internal pins 122 of the reinforcing pin 401 are located inside the housing 91 and respectively connected to the two external pins 121. The two internal pins 122 have as same shape as the internal pins 122 of the lead 92. The coupling part 411 couples the two internal pins 122 of the reinforcing pin 401 to each other. Accordingly, the reinforcing component 94 can be improved in strength. Furthermore, the reinforcing pin 401 has substantially a same shape as a component which consists of the two leads 92 coupled to each other. Therefore, the reinforcing pin 401 and the leads 92 can be formed using, for example, the same mold, thereby facilitating the manufacture of the reinforcing pin 401. In addition, the reinforcing pin 401 and the leads 92 can be attached to the housing 91 in the same manner, thus, the reinforcing pin 401 is easily attached to the housing 91.

Each of the plurality of leads 93 has the internal pin 122 located inside the housing 91 and connected to the external pin 121. The two external pins 121 of the reinforcing pin 401 have a same shape as the external pins 121 of the lead 93. The two internal pins 122 of the reinforcing pin 401 have a same shape as the internal pins 122 of the lead 93. Accordingly, the reinforcing component 94 can be improved in strength. Furthermore, the reinforcing pin 401 has substantially a same shape as a component which consists of the two leads 93 are coupled to each other. Therefore, the reinforcing pin 401 can be easily manufactured and easily attached to the housing 91.

### Fifth Embodiment

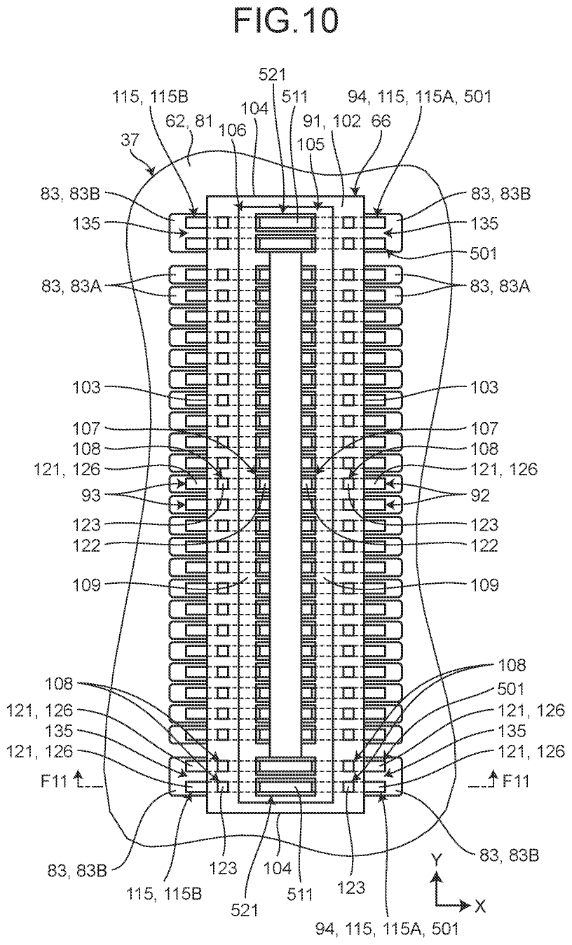

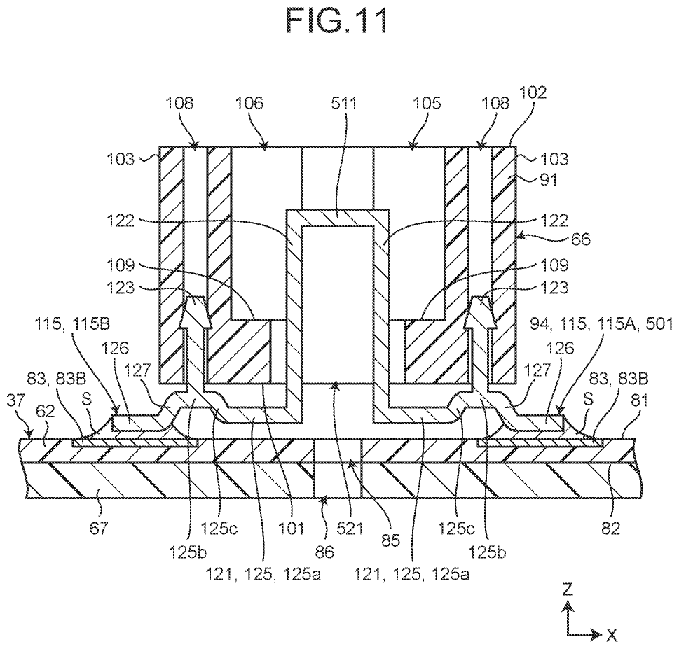

Hereinafter, a fifth embodiment will be described with reference to FIGS. 10 and 11. FIG. 10 is an exemplary plan view illustrating the FPC 37 and the relay connector 66 according to the fifth embodiment. FIG. 11 is an exemplary cross-sectional view of the FPC 37 and the relay connector 66 of the fifth embodiment taken along line F11-F11 in FIG. 10.

As illustrated in FIG. 10, each of the two reinforcing components 94 of the fifth embodiment has two reinforcing pins 501 instead of the reinforcing pins 111 and 112. As illustrated in FIG. 11, each of the two reinforcing pins 501 has lead-like members 115A and 115B.

Each of the two reinforcing pins 501 further includes a coupling part 511. The coupling part 511 is an example of a sixth coupling part and a seventh coupling part. The coupling part 511 of the one reinforcing pin 501 couples one of the two lead-like members 115A to one of the two lead-like members 115B. The coupling part 511 of the other reinforcing pin 501 couples the other of the two lead-like members 115A to the other of the two lead-like members 115B.

The coupling part 511 is connected to the internal pin 122 at an end portion of the internal pin 122 spaced apart from the first connection portion 125a. The coupling part 511 extends in the X direction between the internal pin 122 of the lead-like member 115A and the internal pin 122 of the lead-like member 115B.

In each of the two reinforcing components 94, the two reinforcing pins 501 are arranged at intervals in the Y direction. In other words, one of the two lead-like members 115A and one of the two lead-like members 115B coupled to each other by the one coupling part 511 are spaced apart from the other of the two lead-like members 115A and the other of the two lead-like members 115B coupled to each other by the other coupling part 511. The two reinforcing pins 501 have a common shape or a mirror-symmetrical shape.

The housing 91 of the fifth embodiment is provided with four insertion holes 521 instead of the plurality of insertion holes 107 in which the internal pins 122 of the reinforcing pins 111 and 112 are accommodated. Each of the insertion holes 521 is substantially equal to the insertion hole 107, except as described below.

Each of the four insertion holes 107 extends in the X direction. The plurality of insertion holes 107 are disposed between two of the four insertion holes 521 and the other two of the four insertion holes 521. The internal pin 122 of the reinforcing pin 501 is accommodated in the insertion hole 521. The internal pin 122 passes through the insertion hole 521. The insertion hole 521 is set to a size enabling the internal pins 122 and the coupling parts 511 of the lead-like members 115A and 115B to pass through the insertion hole 521.

In the HDD 10 of the fifth embodiment described above, each of the plurality of leads 93 has the external pin 121 located outside the housing 91. The plurality of leads 93 are attached to the housing 91 in alignment with each other in the Y direction, and spaced apart from the plurality of leads 92 in the −X direction intersecting the Y direction. The reinforcing component 94 includes the two lead-like members 115A, the two lead-like members 115B, and the coupling part 511. The two lead-like members 115A have a same shape as the plurality of leads 92. The two lead-like members 115B have a same shape as the plurality of leads 93. The coupling part 511 couples first one of the two lead-like members 115A to first one of the two lead-like members 115B. Accordingly, the leads 92 and 93 and the lead-like members 115A and 115B can be formed using, for example, the same mold, thereby facilitating the manufacture of the leads 92 and 93 and the lead-like members 115A and 115B. In addition, the leads 92 and 93 and the lead-like members 115A and 115B can be attached to the housing 91 in the same manner, thus, the leads 92 and 93 and the lead-like members 115A and 115B are easily attachable to the housing 91.

The reinforcing component 94 has the coupling part 511 that couples second one of the two lead-like members 115A to second one of the two lead-like members 115B. The first one of the lead-like members 115A and the first one of the lead-like members 115B coupled to each other by first one of the coupling parts 511 are spaced apart from the second one of the lead-like members 115A and the second one of the lead-like members 115B coupled to each other by second one of the coupling parts 511. Therefore, the lead-like members 115A and 115B coupled to each other by the first one of the coupling parts 511 and the lead-like members 115A and 115B coupled to each other by the second one of the coupling part 511 can have a same shape, thus, can be easily formed using the same mold, for example.

### Sixth Embodiment

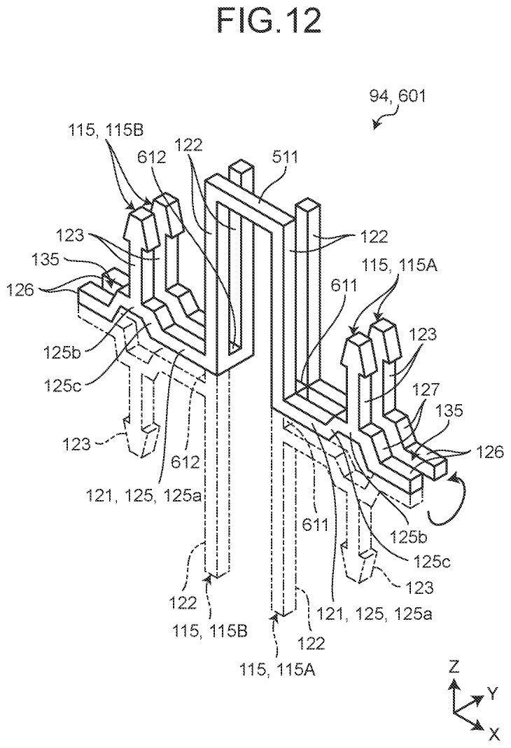

Hereinafter, a sixth embodiment will be described with reference to FIG. 12. FIG. 12 is an exemplary perspective view illustrating a reinforcing pin 601 according to the sixth embodiment. As illustrated in FIG. 12, the reinforcing component 94 of the sixth embodiment has the reinforcing pin 601 instead of the reinforcing pins 111 and 112. The reinforcing pin 601 is substantially equal to the reinforcing pins 111 and 112, except as described below.

The reinforcing pin 601 includes the two lead-like members 115A, the two lead-like members 115B, the coupling part 511, a coupling part 611, and a coupling part 612. The coupling part 611 is an example of an eighth coupling part. The coupling part 612 is an example of a ninth coupling part.

The coupling part 511 couples one of the two lead-like members 115A to one of the two lead-like members 115B. The coupling part 611 couples the two lead-like members 115A to each other. The coupling part 612 couples the two lead-like members 115B to each other.

The coupling parts 611 and 612 are connected to the external pin 121 at a location where the internal pin 122 and the first connection portion 125a are connected to each other. The coupling parts 611 and 612 extends in the Y direction between the two external pins 121. It is noted that the locations of the coupling parts 611 and 612 are not limited to this example.

In the HDD 10 according to the sixth embodiment described above, the reinforcing component 94 includes the coupling part 611 that couples the two lead-like members 115A to each other and the coupling part 612 that couples the two lead-like members 115B to each other. Accordingly, the two lead-like members 115A and the two lead-like members 115B are coupled to each other by the coupling parts 511, 611, and 612, and can be handled as one component. Therefore, the reinforcing component 94 can be easily attached to the housing 91.

### Seventh Embodiment

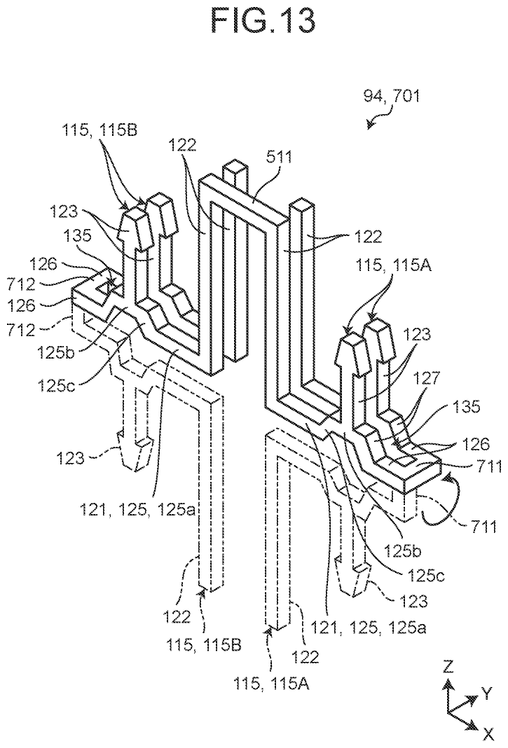

Hereinafter, a seventh embodiment will be described with reference to FIG. 13. FIG. 13 is an exemplary perspective view illustrating a reinforcing pin 701 according to the seventh embodiment. As illustrated in FIG. 13, the reinforcing component 94 of the seventh embodiment has the reinforcing pin 701 instead of the reinforcing pin 601 of the sixth embodiment. The reinforcing pin 701 is substantially equal to the reinforcing pin 601, except as described below.

The reinforcing pin 701 has coupling parts 711 and 712 instead of the coupling parts 611 and 612. The coupling parts 711 and 712 are substantially equal to the coupling parts 611 and 612, except as described below.

Each of the coupling parts 711 and 712 is connected to the external pin 121 at an end portion of the joining portion 126 spaced apart from the inclined portion 127. The coupling parts 711 and 712 extend in the Y direction between the two external pins 121. The coupling parts 711 and 712 are spaced apart from the housing 91.

### Eighth Embodiment

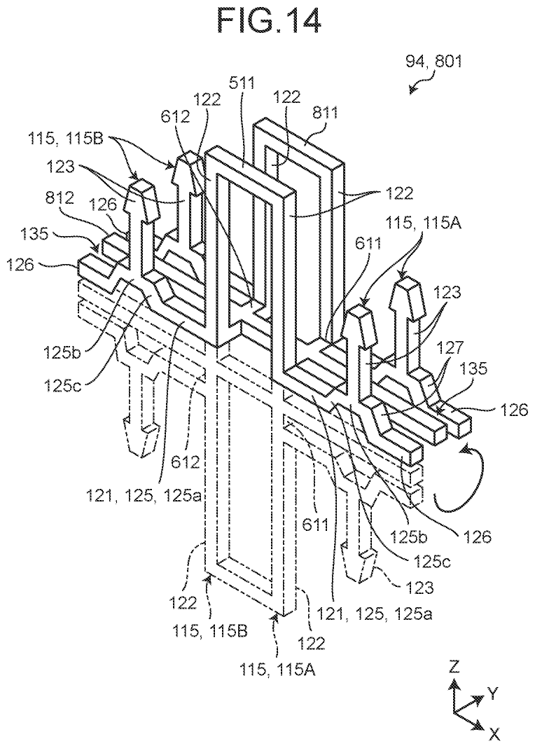

Hereinafter, an eighth embodiment will be described with reference to FIG. 14. FIG. 14 is an exemplary perspective view illustrating a reinforcing pin 801 according to the eighth embodiment. As illustrated in FIG. 14, the reinforcing component 94 of the eighth embodiment further includes a coupling part 811 and an intermediate portion 812 in addition to the configuration of the sixth embodiment.

The coupling part 811 couples the other of the two lead-like members 115A to the other of the two lead-like members 115B. The intermediate portion 812 couples the coupling part 611 and the coupling part 612 to each other. The intermediate portion 812 is spaced apart from the two lead-like members 115A and is spaced apart from the two lead-like members 115B. The intermediate portion 812 extends in the X direction between the coupling part 611 and the coupling part 612.

A part of the intermediate portion 812 is located in-between the two external pins 121 arranged in the Y direction. Therefore, the slit 135 is provided between the one external pin 121 and the intermediate portion 812, and the slit 135 is also provided between the other external pin 121 and the intermediate portion 812.

### Ninth Embodiment

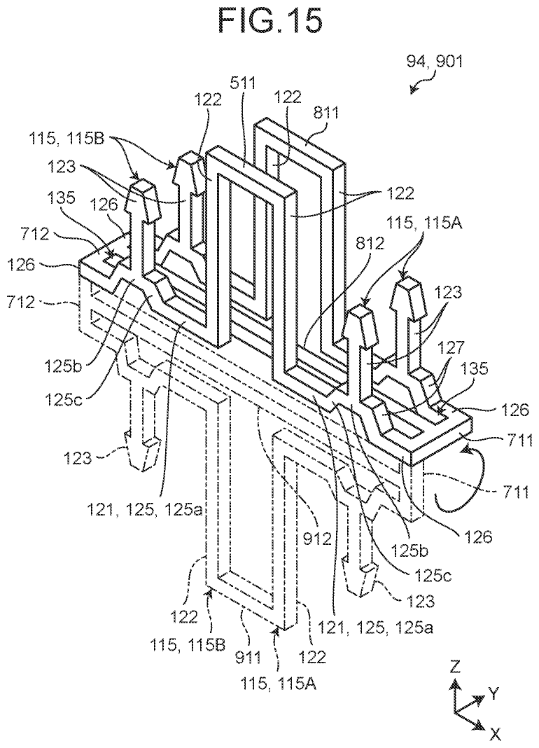

Hereinafter, a ninth embodiment will be described with reference to FIG. 15. FIG. 15 is an exemplary perspective view illustrating a reinforcing pin 901 according to the ninth embodiment. As illustrated in FIG. 15, the reinforcing component 94 of the ninth embodiment further includes a coupling part 811 and an intermediate portion 812 in addition to the configuration of the seventh embodiment. In the ninth embodiment, the intermediate portion 812 couples the coupling part 711 and the coupling part 712 to each other.

### Modification

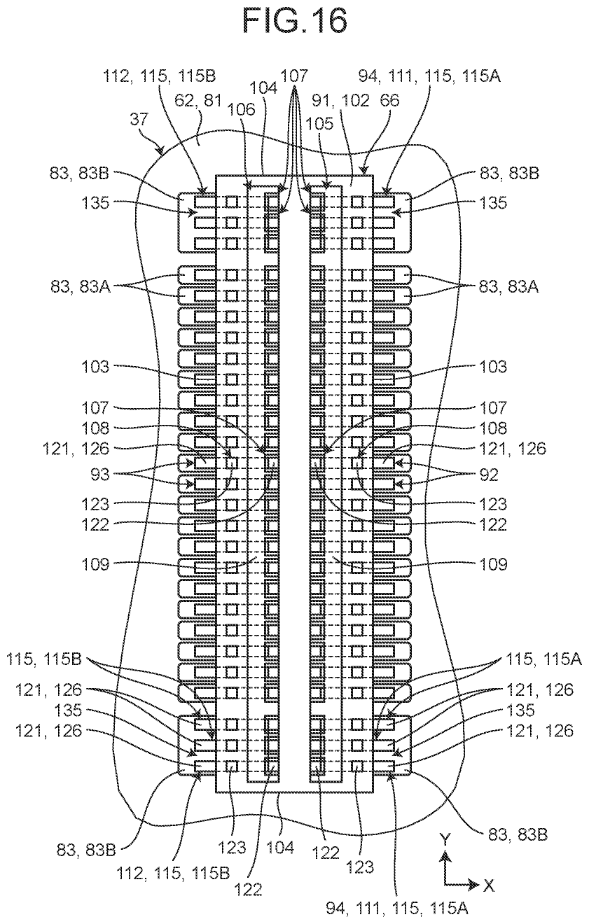

FIG. 16 is an exemplary plan view illustrating the FPC 37 and the relay connector 66 according to a modification of the first embodiment. As illustrated in FIG. 16, each of the two reinforcing components 94 may have three or more external pins 121 arranged in the Y direction. For example, each of the reinforcing pins 111 and 112 may have three or more lead-like members 115.

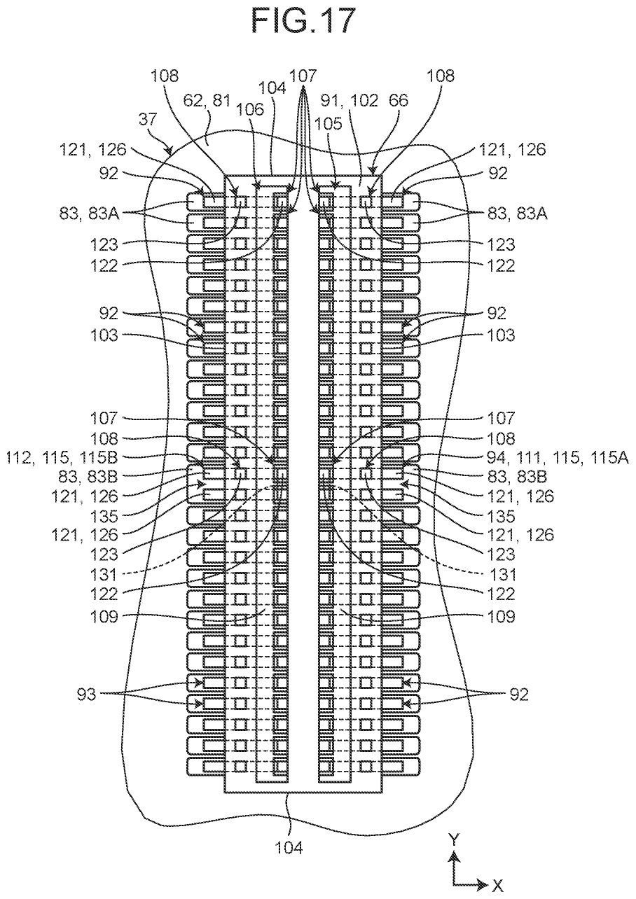

FIG. 17 is an exemplary plan view illustrating the FPC 37 and the relay connector 66 according to another modification of the first embodiment. As illustrated in FIG. 17, the reinforcing pin 111 may be located between at least one of the plurality of leads 92 and at least the other one of the plurality of leads 92. Similarly, the reinforcing pin 112 may be located between at least one of the plurality of leads 93 and at least the other one of the plurality of leads 93. For example, the reinforcing component 94 may be mounted in the center of the housing 91.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A connector comprising:
a housing;
a plurality of first leads being attached to the housing in alignment with each other in a first direction, each of which includes a first external terminal outside the housing; and
a metal component with a first opening, being attached to the housing, the metal component including
two first junction terminals being aligned with the first external terminals of the plurality of first leads in the first direction outside the housing, the first opening being located in-between the two first junction terminals.

2. The connector according to claim 1, wherein
the metal component includes a first coupling part that couples the two first junction terminals to each other.

3. The connector according to claim 2, wherein
the metal component includes a second coupling part that couples the two first junction terminals to each other, and
the first opening is located between the first coupling part and the second coupling part.

4. The connector according to claim 2, wherein
the two first junction terminals have a same shape or are mirror-symmetric to each other.

5. The connector according to claim 2, wherein
the metal component includes two lead-like members each of which includes one of the two first junction terminals, and
the plurality of first leads and the two lead-like members have a same shape.

6. The connector according to claim 1, wherein
each of the plurality of first leads includes a first internal terminal located inside the housing and connected to the first external terminal,
the two first junction terminals and the plurality of first external terminals have a same shape, and
the metal component includes:
two first terminal-like parts having a same shape as the first internal terminal, and being located inside the housing and connected to the two first coupling terminals; and
a third coupling part that couples the two first terminal-like parts to each other.

7. The connector according to claim 2, further comprising
a plurality of second leads being attached to the housing in alignment with each other in the first direction and spaced apart from the plurality of first leads in a second direction intersecting the first direction, the plurality of second leads each of which includes a second external terminal outside the housing,
wherein the metal component includes:
two second junction terminals being juxtaposed to each other in the first direction outside the housing; and
a fourth coupling part that couples the two second junction terminals to each other,
the second external terminals of the plurality of second leads and the two second junction terminals are aligned with each other in the first direction, and
the metal component is provided with a second opening in-between the two second junction terminals.

8. The connector according to claim 7, wherein
the two first junction terminals and the two second junction terminals have a same shape or are mirror-symmetric to each other.

9. The connector according to claim 6, further comprising
a plurality of second leads being attached to the housing in alignment with each other in the first direction and spaced apart from the plurality of first leads in a second direction intersecting the first direction, the plurality of second leads each of which includes
a second external terminal located outside the housing, and
a second internal terminal located inside the housing and connected to the second external terminal, wherein the metal component includes:
two second junction terminals having a same shape as the plurality of second external terminals and being juxtaposed to each other in the first direction outside the housing;
two second terminal-like parts having a same shape as the second internal terminal, located inside the housing, and connected to the two second junction terminals; and
a fifth coupling part that couples the two second terminal-like parts to each other,
the second external terminals of the plurality of second leads and the two second junction terminals are aligned with each other in the first direction, and
the metal component is provided with a second opening in-between the two second junction terminals.

10. The connector according to claim 1, further comprising
a plurality of second leads being attached to the housing in alignment with each other in the first direction and spaced apart from the plurality of first leads in a second direction intersecting the first direction, the plurality of second leads each of which includes a second external terminal outside the housing,
wherein the metal component includes:
two first lead-like members having a same shape as the plurality of first leads;
two second lead-like members having a same shape as the plurality of second leads; and
a sixth coupling part that couples a first one of the two first lead-like members to a first one of the two second lead-like members; and
each of the two first lead-like members includes one of the two first junction terminals.

11. The connector according to claim 10, wherein
the metal component includes a seventh coupling part that couples a second one of the two first lead-like members to a second one of the two second lead-like members, and
the first one of the two first lead-like members and the first one of the two second lead-like members coupled to each other by the sixth coupling part are spaced from the second one of the two first lead-like members and the second one of the two second lead-like members coupled to each other by the seventh coupling part.

12. The connector according to claim 10, wherein
the metal component includes an eighth coupling part that couples the two first lead-like members to each other, and a ninth coupling part that couples the two second lead-like members to each other.

13. The connector according to claim 1, wherein
an interval between the two first junction terminals is shorter than or equal to an interval between the plurality of first leads.

14. The connector according to claim 1, wherein
one of the two first junction terminals is located at an end of a row of the first external terminals of the plurality of first leads and the two first junction terminals.

15. A disk device comprising:
the connector according to claim 1; and
a substrate including
a plurality of first pads to which the first external terminals of the plurality of first leads are joined, and
a second pad to which the two first junction terminals are joined.

16. The disk device according to claim 15, wherein
the second pad is set to a ground potential.

17. The disk device according to claim 15, further comprising
a corresponding connector being connected to the connector,
wherein the corresponding connector includes a ground terminal electrically connected to the metal component and set to a ground potential.

18. A connector comprising:
a housing;
a plurality of leads being attached to the housing in two rows in a first direction and having a same shape, each of which includes an external terminal located outside the housing; and
a coupling part that couples two adjacent leads to each other among the plurality of leads.
